(19) United States
(12) Patent Application Publication
(10) Pub. No.: US 2025/0300423 A1
(43) Pub. Date: Sep. 25, 2025

(54) DOT PROJECTOR WITH AUTOMATIC POWER WRITE

(71) Applicant: ARIMA LASERS CORP., TAOYUAN CITY (TW)

(72) Inventors: Po Han CHEN, Taoyuan City (TW); Chun Ting LIN, Taoyuan City (TW); Chun Yu LIN, Taoyuan City (TW)

(73) Assignee: ARIMA LASERS CORP., TAOYUAN CITY (TW)

(21) Appl. No.: 18/668,365

(22) Filed: May 20, 2024

(30) Foreign Application Priority Data
Mar. 19, 2024 (TW) 113110208

(51) Int. Cl. H01S 5/02212; H01S 5/026; H01S 5/068; H01S 5/0683

(52) U.S. Cl. CPC H01S 5/02212; H01S 5/0262; H01S 5/06808; H01S 5/06825; H01S 5/0683

(57) ABSTRACT

A dot projector with automatic power write is manufactured as a printed circuit board or an integrated circuit, and is directly arranged on a base to control the laser power; a photodiode arranged on the APW IC; a PWM controller, connected to the third pin for writing functions to set the laser output power and PWM to adjust the laser rate; an adjustment circuit, connected between the photodiode, changing the resistance value of a resistor according to a trim code, which uses a decoder to select different resistance values for writing, and the pin to which it is written is the same as the third pin of the PWM control.

### BACKGROUND OF THE INVENTION

### 1. Field of the Invention

The invention relates to a dot projector, particularly to one that has function of automatic power write.

### 2. Description of the Related Art

Since the advent of laser diodes (LD), it has been used in many fields such as optical communications, optical recording and optical storage. Laser diodes (LD) come in two types: edge-emitting and surface-emitting. Among them, surface-emitting LD must be packaged to prevent dust from entering and eliminate the impact of ambient temperature changes on its performance to ensure the stability of its products.

The conventional LD packaging method adopts a TO-CAN frame; referring to FIG. 1, the LD package (100) includes: a base (110), a plurality of electrical connection terminals (120), and a photodetector (130), a laser device (140), a packaging cover (150) and an optical lens (160). Similar patents can be found in prior art such as U.S. Pat. No. 5,835,514.

The luminous characteristics of laser diodes are easily affected by the ambient temperature. As the current and optical power increase during driving, the components will also generate a higher temperature, further causing the optical attenuation to increase. Therefore, general semiconductor lasers are equipped with external circuits to control the input current and use feedback control to detect the optical power output and instantly compensate for the attenuation of laser optical power caused by temperature.

Referring to FIG. 2A, the prior art of our own invention, Taiwan Patent No. M386685, a laser diode device (900), which includes: a base (200), which in this embodiment is structured in the form of a lead frame (200a), provided with three conductive junctions (210), and the conductive junctions (210) respectively extend out of the lead frame (200a) to form a first pin (211), a second pin (212) and a third pin (213). Further referring to FIG. 2B, the first pin (211) and the second pin (212) are connected to the positive and negative power supplies respectively, and the third pin (213) is connected to an external resistor (800) to set the laser power. A photodetector mounting seat (300) is provided on the surface of the lead frame (200a) for detecting laser power and carrying a laser diode die (500). The photodetector mounting seat (300) is provided with a photodetector (400) structure. An automatic power control circuit (APC) (600) is configured in the form of a circuit board or IC and is directly installed on the base (200) so that it is packaged in the same package of laser diode die (500). And it is electrically connected to the predetermined conductive junction (210), the laser diode die (500) and the photodetector (400) through wire bonding (700) form the driving element of the laser diode, then further form a laser diode device (500) with a built-in APC circuit; however, this prior art uses the third pin (213) to connect the external resistor (800) to set the laser power, and the external resistor (800) is a variable resistor (VR).

Moreover, another prior art of our own invention, U.S. Pat. No. 10,418,780 B1 provide a dot projector with automatic power control that has a substrate integrating an automatic power control integrated circuit (IC), a mounting seat, a laser diode, a reflector, a housing, a collimator and a diffractive optical element (DOE) to improve the complex structure with greater volume of a conventional device that cannot be applied to surface mount technology. Referring to FIG. 3, a structure of the automatic power control IC 32 further includes having the voltage input pin P1 series connected to the photodiode 321 and parallel connected to a resistor R and a first electrostatic discharge (ESD) circuit E1 that is parallel connected to a ground pin G, a logic circuit LE separately connected to the resistor R and the current setting pin P3 in series connection, a current amplifier CA series connected to the photodiode 321, an error amplifier EA parallel connected to the current amplifier CA, a protection circuit U parallel connected to the error amplifier EA and including a voltage reference unit U1, an overheat protection unit U2 and an undervoltage-lockout unit U3, a transistor T separately connected to the error amplifier EA, the laser diode (34) output pin P5 and the ground pin G in series connection, a current monitoring circuit CM parallel connected to the ground pin G, a second ESD circuit E2 separately connected to the current setting pin CM and the ground pin G in parallel connection, a third ESD circuit E3 separately connected to the current setting pin CM and the ground pin G in parallel connection, a variable resistor VR separately connected to the photodiode output pin P4 and the ground pin G in series connection.

However, the laser power adjustment in the prior art is achieved through the external variable resistor (VR); for the production of dot projector, there are still problems such as complex assembly, large size and high cost, so it requires improvement.

### SUMMARY OF THE INVENTION

It is a primary objective of the present invention is to provide a dot projector with automatic power write, and having the effect of detecting the optical power value of the laser diode by the photodiode, and the optical power change is notified through circuit feedback and current compensation is made immediately, so that the optical power can be stably maintained at the power value written by the automatic power write circuit (APW IC).

Another objective of the present invention is to provide a dot projector with automatic power write, designed with IC form with a protection circuit that allows the user to safely control the laser diode, then packaged in a single TO-CAN, so as to achieve small size and low cost.

In order to achieve the above objectives, the dot projector with automatic power write, includes: a base, the base is configured in the form of a TO-CAN package lead frame, and is provided with a first pin, a second pin and a third pin, and the first pin and second pin are respectively connected to the positive and negative power supplies; a laser diode mounted on a mounting seat of the base; a photodiode, arranged on the light emitting surface of the laser diode for detecting laser power;
wherein: an automatic power write circuit (APW IC) is manufactured as a printed circuit board or an integrated circuit, and is directly arranged on the base to control the laser power; the photodiode is arranged on the automatic power write circuit; the automatic power write circuit includes: the first pin is series connected to the photodiode and parallel connected to a first electrostatic discharge circuit, the first electrostatic discharge circuit further parallel connected to a ground pin; a logic circuit is coupled to the first pin and the third pin; an error amplifier parallel connected to the photodiode, responsible for the circuit and determining the laser diode current; a protection circuit connected to the error amplifier as a reference voltage and to prevent low voltage malfunction; a transistor separately connected to the error amplifier, a laser diode output pin and the ground pin in series connection; a current monitoring circuit parallel connected to the transistor and coupled to the ground pin; a PWM controller, connected to the third pin and coupled between the error amplifier and the transistor for writing functions to set the laser output power and PWM to adjust the laser rate; and an adjustment circuit, connected between the photodiode and the ground pin, the adjustment circuit changes the resistance value of a resistor according to a trim code (TRC), which uses a decoder to output to select different resistance values for writing, and the pin to which it is written is the same as the third pin of the PWM control; Whereby, the photodiode detects the optical power value of the laser diode, notifies the optical power change in the form of circuit feedback, and immediately makes current compensation, so that the optical power can be stably maintained at the power value written by the automatic power write circuit (APW IC).

Also, the adjustment circuit connects a plurality of switches SW1, SW2 to SWn at multiple joint positions of the resistor, selectively turns on the switches SW1 to SWn according to the trim code (TRC), and short-circuits a part of the resistor, thereby changing the resistance value.

Also, the automatic power write circuit further includes a second electrostatic discharge circuit arranged between the laser diode output pin and the ground pin; and a third electrostatic discharge circuit connected in parallel with the third pin and the ground pin.

Also, the automatic power write circuit further includes a soft start circuit for preventing overcurrent during activation of the dot projector, and a unidirectional diode is provided between the first pin and the photodiode.

Also, the base further includes a metal cover and a coated glass.

Also, the protection circuit further includes an over current protection, an over temperature protection, a short circuit protection, and a reverse voltage protection.

Whereby, the present invention provides a TO-CAN package lead frame with the photodiode and APW IC to detect the optical power value of the laser diode, notifies the optical power change in the form of circuit feedback, and immediately makes current compensation, so that the optical power can be stably maintained at the power value written by the APW IC. At the same time, the IC is designed with safety protection such as a protection circuit, allowing users to safely control the laser diode, which is packaged in a single TO-CAN to achieve the goals of small size and low cost.

### BRIEF DESCRIPTION OF THE DRAWINGS

FIG. 1 is a schematic diagram of the structure of the conventional LD with a single TO-CAN package;

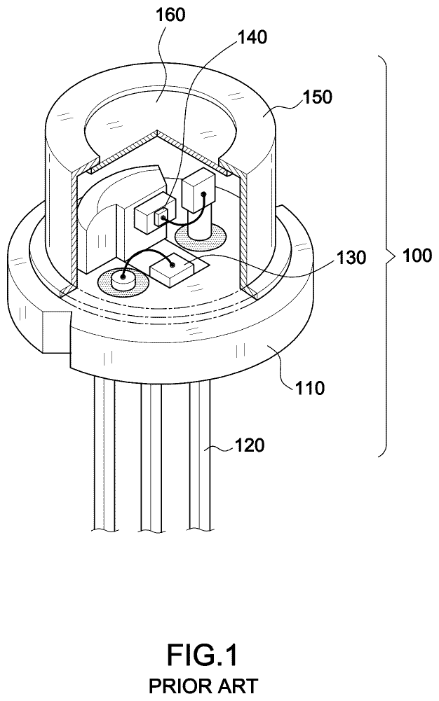

FIG. 2A is a schematic diagram of the prior art Taiwan Patent No. M386685;

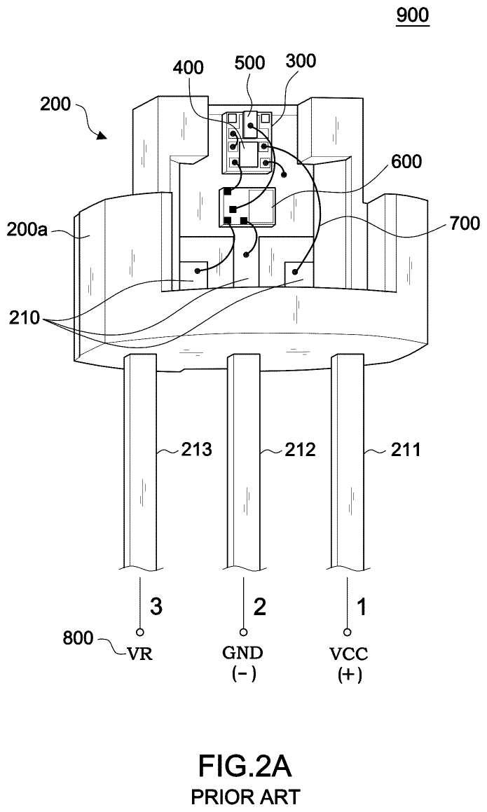

FIG. 2B is a circuit diagram illustrating the APC circuit of the prior art Taiwan Patent No. M386685;

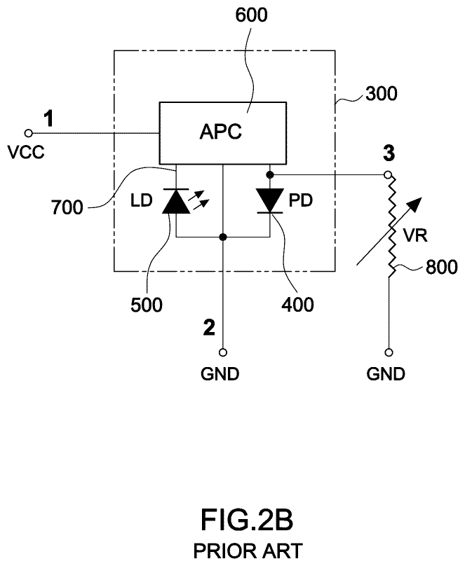

FIG. 3 is a schematic diagram showing the circuit structure of the automatic power control of the conventional LD;

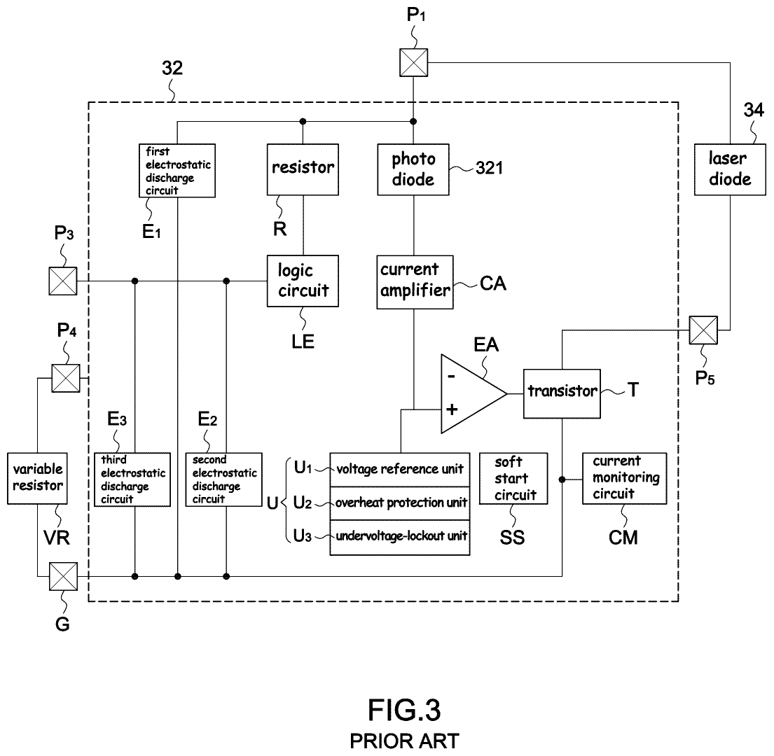

FIG. 4A is a schematic diagram of the structure of a preferred embodiment of the present invention;

FIG. 4B is a sectional view of the structure of a preferred embodiment of the present invention;

FIG. 5 is a schematic diagram showing the circuit structure of a preferred embodiment of the present invention;

FIG. 6 is a schematic diagram showing the adjustment circuit of a preferred embodiment of the present invention;

FIG. 7 is a schematic diagram showing the automatic power write of a preferred embodiment of the present invention.

### DETAILED DESCRIPTION OF THE PREFERRED EMBODIMENT

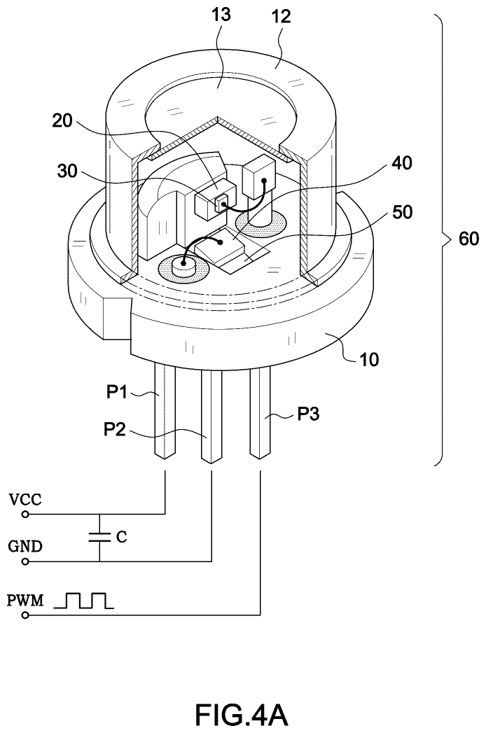

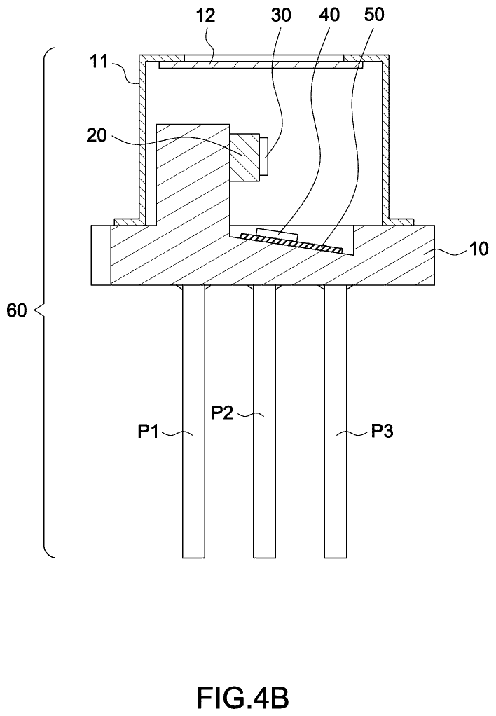

Referring to FIGS. 4A-7 which shows a preferred embodiment of the present invention, a dot projector with automatic power write 60, comprising: a base 10, which is formed by a heat sink. In this embodiment, the base 10 is configured in the form of a TO-CAN package lead frame, and is provided with a first pin P1, a second pin P2 and a third pin P3, and the first pin P1 and second pin P2 are respectively connected to the positive and negative power supplies, the first pin P1 is a VCC, and the second pin P2 is a ground terminal (GND).

Referring to FIGS. 4A and 4B, a laser diode (LD) 30 mounted on a mounting seat 20 of the base 10, a photodiode 40, arranged on the light emitting surface of the laser diode 30 for detecting laser power; in this embodiment, the TO-CAN package lead frame further includes a metal cap 11 to package and protect the laser diode (LD) 30 and the photodiode (PD) 40, the light of the laser diode 30 is output through a coated glass 12, and then the package components are fixed on the base 10 for heat dissipation.

The main feature of the present invention includes: an automatic power write circuit 50 (APW IC) is manufactured as a printed circuit board or an integrated circuit, and is directly arranged on the base 10 to control the laser power; the photodiode 40 is arranged on the automatic power write circuit 50.

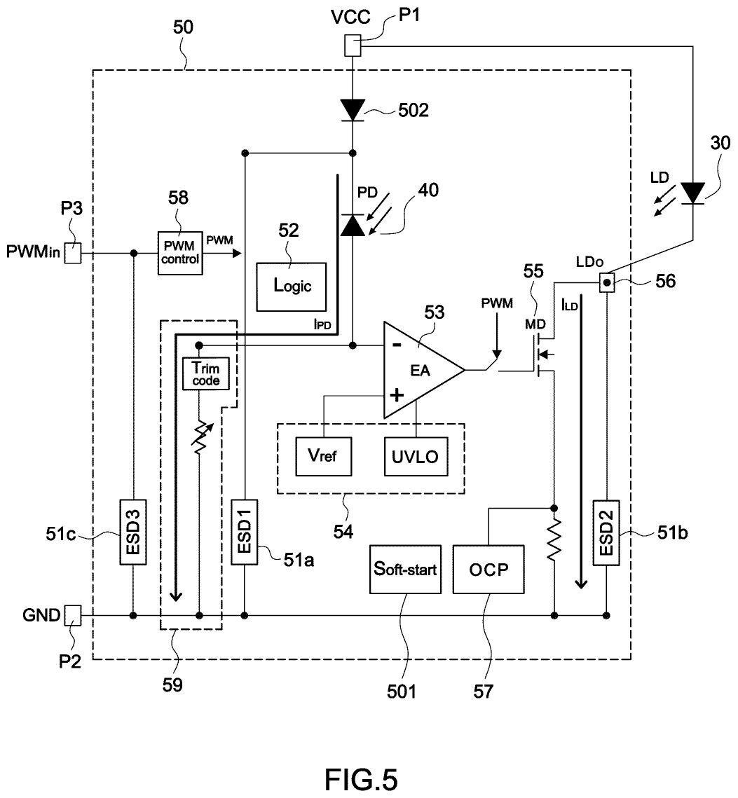

Referring to FIG. 5 which shows a preferred embodiment of the present invention, the automatic power write circuit 50, comprising: the first pin P1 is series connected to the photodiode 40 and parallel connected to a first electrostatic discharge circuit (ESD1) 51a, the first electrostatic discharge circuit 51a further parallel connected to a ground pin (GND); a logic circuit 52 is coupled to the first pin P1 and the third pin P3; an error amplifier 53 parallel connected to the photodiode 40, responsible for the circuit and determining the laser diode 30 current.

A protection circuit 54 composed of a voltage reference (Vref) and a under voltage lock out (UVLO), and respectively connected to the input end and output end of the error amplifier 53 as a reference voltage and to prevent low voltage malfunction; In this embodiment, the protection circuit 54 further includes an over current protection, an over temperature protection, a short circuit protection, and a reverse voltage protection.

A transistor (MD) 55 separately connected to the error amplifier 53, a laser diode output pin (LDo) 56 and the ground pin (GND) in series connection; a current monitoring circuit (OCP) 57 parallel connected to the transistor 55 and coupled to the ground pin (GND).

A PWM controller 58, connected to the third pin P3 and coupled between the error amplifier 53 and the transistor 55 for writing functions to set the laser output power and PWM to adjust the laser rate.

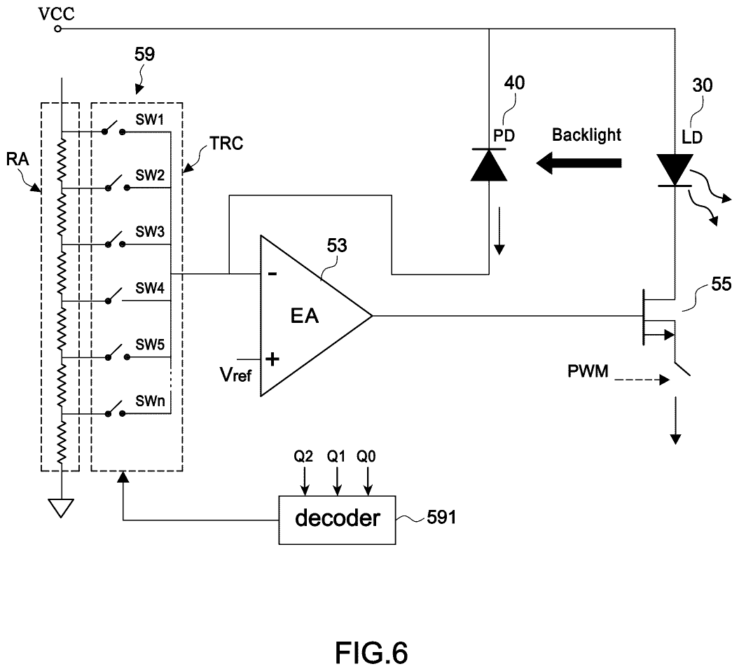

An adjustment circuit 59, connected between the photodiode 40 and the ground pin (GND), the adjustment circuit 59 changes the resistance value of a resistor RA according to a trim code (TRC). As FIG. 6 showing, the adjustment circuit 59 connects a plurality of switches SW1, SW2 to SWn at multiple joint positions of the resistor RA, selectively turns on the switches SW1 to SWn according to the trim code (TRC), and short-circuits a part of the resistor RA, thereby changing the resistance value. In this embodiment, uses a decoder 591 to output to select different resistance values for writing, and the pin to which it is written is the same as the third pin P3 of the PWM control 58; Furthermore, when power is supplied, the logic circuit 52 outputs the trim code (TRC) to the resistor RA based on the setting information stored in the memory.

Whereby, the photodiode 40 detects the optical power value of the laser diode 30, notifies the optical power change in the form of circuit feedback, and immediately makes current compensation, so that the optical power can be stably maintained at the power value written by the automatic power write circuit 50 (APW IC).

In this embodiment, the automatic power write circuit 50 further includes a second electrostatic discharge circuit (ESD2) 51b arranged between the laser diode output pin (LDo) 56 and the ground pin (GND); and a third electrostatic discharge circuit (ESD3) 51c connected in parallel with the third pin P3 and the ground pin (GND). Furthermore, the automatic power write circuit 50 further includes a soft start circuit 501 for preventing overcurrent during activation of the dot projector, and a unidirectional diode 502 is provided between the first pin P1 and the photodiode 40.

Also, the dot projector with automatic power write 60 of the present invention is a three-pin structure that combines the automatic power write circuit 50 with a TO-CAN package. By this matter, the IC is designed to achieve the compensation control and the circuit protection, the three external pins of TO-CAN are divided into three types: VCC, GND, and PWM, as showing in FIG. 4A. Generally, the positive and negative terminals of power supply VCC (+) and GND (−) are necessary pins, the remaining third pin P3 is designed to be able to write optical power, after the writing is completed, it has the function of controlling the optical signal through PWM, so the third pin P3 has two functions: “writing function for setting laser output power” and “adjustment laser power with PWM”.

Generally, it is not difficult for making an IC to has writing functions. However, to achieve using a laser diode to write optical power on a limited three pins, and using PWM signals to control changes of optical power are difficult. Therefore, the present invention first preliminarily designs a conceptual diagram as showing in FIG. 6. This circuit concept is mainly that the photocurrent value of the backlight generated by the laser diode (LD) 30 projection on the photodiode (PD) 40 is looped with the error amplifier (EA) 53 to determine the current value provided to the laser diode (LD) 30, and is written through the resistance value selected by the decoder 591.

After the resistance value is written, a fixed current value will be provided to the laser diode (LD) 30 after the dot projector with automatic power write 60 is driven, and simultaneously generated a fixed output optical power rate, but this pin of writing the resistance value does not has other function. In order to further improve the design of the automatic power writing (APW), the present invention let the third pin P3 to be connected to the PWM control block, so that the dot projector with automatic power write 60 can use the PWM signal to adjust the optical power rate, so as to achieve a light signal can adjust PWM.

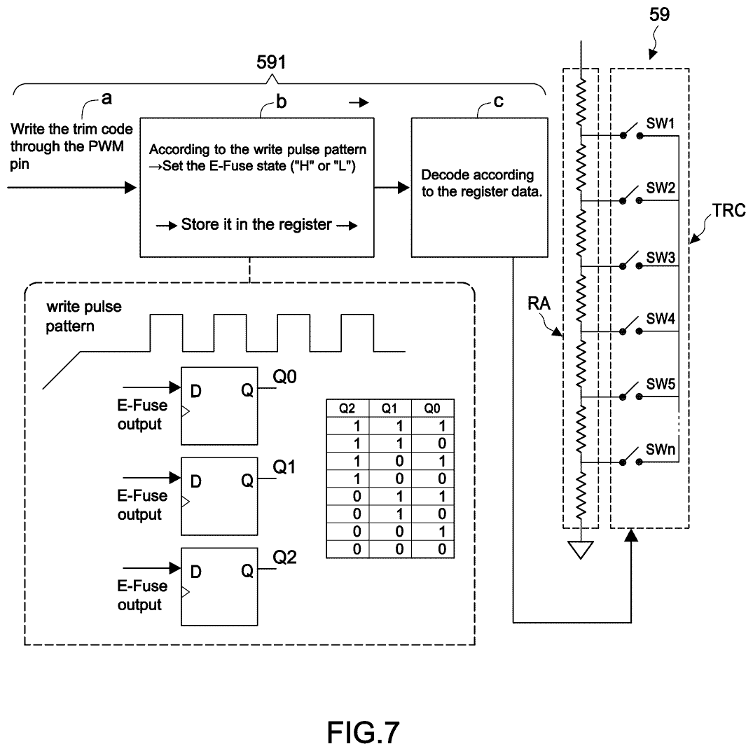

FIG. 7 discloses a schematic diagram of the automatic power writing (APW) using the decoder 591, the step is:
(a). Write the trim code through the PWM pin (third pin P3);
(b). According to the write pulse pattern→Set the E-Fuse state (“H” or “L”)→Store it in the register;
(c). Decode according to the register data.

With the features above disclosed, the adjustment circuit 59 showing in the blocks showing in FIGS. 5 to 7 is using the decoder 591 to select different resistance values for writing, because the writing pin is the same pin as the PWM (third pin P3), so it is set with a special mode to achieve the trim code TRC writing condition. After writing is completed, it becomes a PWM function pin to control the PWM signal of the laser diode.

Therefore, the APW design of the present invention maintains the original three-pin structure of the TO-CAN package, also can additionally write codes into the APW IC, after the laser is driven, it can directly reach the target optical power value and be maintained at all times. After the IC is written, the third pin P3 can become the control pin of the PWM signal, as long as the PWM signal is provided, the output light signal of the laser can produce a synchronous PWM effect at the same time.

With the features above disclosed, the present invention has the effect of detecting the optical power value of the laser diode 30 by the photodiode 40, and the optical power change is notified through circuit feedback and current compensation is made immediately, so that the optical power can be stably maintained at the power value written by the automatic power write circuit (APW IC). Also, the present invention designed with IC form with a protection circuit that allows the user to safely control the laser diode, then packaged in a single TO-CAN, so as to achieve small size and low cost.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A dot projector with automatic power write, comprising:
a base, the base is configured in the form of a TO-CAN package lead frame, and is provided with a first pin, a second pin and a third pin, and the first pin and second pin are respectively connected to the positive and negative power supplies;
a laser diode mounted on a mounting seat of the base;
a photodiode, arranged on the light emitting surface of the laser diode for detecting laser power;
wherein:
an automatic power write circuit (APW IC) is manufactured as a printed circuit board or an integrated circuit, and is directly arranged on the base to control the laser power; the photodiode is arranged on the automatic power write circuit; the automatic power write circuit includes:
the first pin is series connected to the photodiode and parallel connected to a first electrostatic discharge circuit, the first electrostatic discharge circuit further parallel connected to a ground pin;
a logic circuit is coupled to the first pin and the third pin;
an error amplifier parallel connected to the photodiode, responsible for the circuit and determining the laser diode current;
a protection circuit connected to the error amplifier as a reference voltage and to prevent low voltage malfunction;
a transistor separately connected to the error amplifier, a laser diode output pin and the ground pin in series connection;
a current monitoring circuit parallel connected to the transistor and coupled to the ground pin;
a PWM controller, connected to the third pin and coupled between the error amplifier and the transistor for writing functions to set the laser output power and PWM to adjust the laser rate; and
an adjustment circuit, connected between the photodiode and the ground pin, the adjustment circuit changes the resistance value of a resistor according to a trim code (TRC), which uses a decoder to output to select different resistance values for writing, and the pin to which it is written is the same as the third pin of the PWM control;
Whereby, the photodiode detects the optical power value of the laser diode, notifies the optical power change in the form of circuit feedback, and immediately makes current compensation, so that the optical power can be stably maintained at the power value written by the automatic power write circuit (APW IC).

2. The dot projector with automatic power write as claimed in claim 1, wherein the adjustment circuit connects a plurality of switches SW1, SW2 to SWn at multiple joint positions of the resistor, selectively turns on the switches SW1 to SWn according to the trim code (TRC), and short-circuits a part of the resistor, thereby changing the resistance value.

3. The dot projector with automatic power write as claimed in claim 1, wherein the automatic power write circuit further includes a second electrostatic discharge circuit arranged between the laser diode output pin and the ground pin; and a third electrostatic discharge circuit connected in parallel with the third pin and the ground pin.

4. The dot projector with automatic power write as claimed in claim 1, wherein the automatic power write circuit further includes a soft start circuit for preventing overcurrent during activation of the dot projector, and a unidirectional diode is provided between the first pin and the photodiode.

5. The dot projector with automatic power write as claimed in claim 1, wherein the base further includes a metal cover and a coated glass.

6. The dot projector with automatic power write as claimed in claim 1, wherein the protection circuit further includes an over current protection, an over temperature protection, a short circuit protection, and a reverse voltage protection.
